(19) United States
(12) Patent Application Publication
(10) Pub. No.: US 2026/0332088 A1
(43) Pub. Date: Oct. 22, 2026

(54) PHOTOVOLTAIC POWER GENERATION MODULE

(71) Applicant: LG INNOTEK CO., LTD., Seoul (KR)

(72) Inventors: Seung Min LEE, Seoul (KR); Kwang Soon JUNG, Seoul (KR); Soo Hong KIM, Seoul (KR)

(73) Assignee: LG INNOTEK CO., LTD., Seoul (KR)

(21) Appl. No.: 19/116,680

(22) PCT Filed: Sep. 27, 2023
(86) PCT No.: PCT/KR2023/015154

§ 371 Date: Mar. 28, 2025

(30) Foreign Application Priority Data
Sep. 30, 2022 (KR) 10-2022-0125805

(51) Int. Cl. H02S 40/34; H02J 3/38; H02J 101/24

(52) U.S. Cl. CPC H02S 40/34; H02J 3/38; H02J 2101/25

(57) ABSTRACT

A photovoltaic power generation module according to one embodiment of the present invention comprises: a photovoltaic power generation panel including a plurality of cell strings; and a plurality of optimizers, each controlling the output power of each cell strings, wherein each optimizer is located at a position corresponding to an output terminal of each cell string.

### TECHNICAL FIELD

The present invention relates to photovoltaic modules, and more particularly to photovoltaic modules in which optimizers are connected individually to each photovoltaic cell string.

### BACKGROUND ARTS

Solar power generation is an eco-friendly energy generation method that is replacing conventional chemical and nuclear power generation and is becoming widely used. Solar power generation can be either stand-alone, where the battery is connected to a converter, or grid-connected, which is connected to the power grid. Generally, stand-alone power generation is composed of photovoltaic cells, storage batteries, and power converters, while grid-connected systems are connected to commercial power sources and are configured to exchange power with the load line.

The maximum power point of a photovoltaic module varies depending on the amount of sunlight and temperature. To operate the solar cell at the maximum power point, an optimizer or module-level power electronics (MLPE) can be used to control the maximum power point tracking (MPPT) at the module level.

A junction box is installed on the photovoltaic module to connect it to an external line. To connect the optimizer to the photovoltaic module, a large number of cables and manual work are required. There is also the disadvantage that a separate device must be installed to prevent electric shock on the photovoltaic module depending on the installation environment.

### SUMMARY OF THE INVENTION

### Technical Subject

The technical challenge that this invention seeks to solve is to provide a photovoltaic module in which the optimizer is connected individually to each photovoltaic cell string.

### Technical Solution

To solve the above-mentioned technical problems, a photovoltaic module according to one exemplary embodiment of the present invention may comprise: a photovoltaic panel including a plurality of cell strings; and a plurality of optimizers each controlling the output power of each of the cell strings, each optimizer being located at a position corresponding to an output terminal of each of the cell strings.

Preferably, but not necessarily, each of the optimizers may include two input terminals connected to the output terminals at both ends of each of the cell strings; two output terminals connected to another optimizer or outside; and a power conversion unit that converts the output power of each of the cell strings inputted through the input terminals and outputs it to the output terminals.

Preferably, but not necessarily, the output terminal connected to the other optimizer may be connected via the connection unit embedded in the photovoltaic panel.

Preferably, but not necessarily, the connection unit embedded in the photovoltaic panel may include a bus bar or a cable.

Preferably, but not necessarily, the output terminals at both ends of each of the cell strings may be directly connected to the two input terminals of each of the optimizers and inside the optimizer.

Preferably, but not necessarily, the output terminal connected to the optimizer or the outside may be connected via the connection unit outside the photovoltaic panel.

Preferably, but not necessarily, the power conversion unit may include at least one of a buck converter, a boost converter, and a buck-boost converter.

Preferably, but not necessarily, each optimizer may include a bypass unit connected in parallel between the two output terminals.

Preferably, but not necessarily, each optimizer may control the output power of each cell string with maximum power point tracking (MPPT).

Preferably, but not necessarily, the plurality of optimizers may be mounted on the opposite surface of the surface on which the photovoltaic module is placed.

### Advantageous Effects

According to exemplary embodiments of the present invention, it is possible to reduce the number of cables for connecting photovoltaic panels and optimizers and to facilitate work.

### BRIEF DESCRIPTION OF DRAWINGS

FIG. 1 is a block diagram of a photovoltaic module according to an exemplary embodiment of the present invention.

FIG. 2 is a drawing for explaining the maximum power point tracking control.

FIG. 3 is a block diagram that specifies the relationship between the cell string and the optimizer according to an embodiment of the present invention.

FIG. 4 shows the connected relationship between optimizers according to an embodiment of the present invention.

FIG. 5 shows the position of each optimizer according to an embodiment of the present invention.

FIG. 6 shows an embodiment of a photovoltaic module according to an embodiment of the present invention.

FIG. 7 is a block diagram of an optimizer module according to an embodiment of the present invention.

FIG. 8 shows an embodiment of an optimizer module according to an embodiment of the present invention.

FIG. 9 is a block diagram of a photovoltaic module according to another embodiment of the present invention.

FIG. 10 is a perspective view of an optimizer module according to an embodiment of the present invention.

FIG. 11 shows the inside of the case of an optimizer module according to an embodiment of the present invention.

FIG. 12 shows the connected relationship of multiple optimizer modules according to an embodiment of the present invention.

FIG. 13 is a block diagram of a photovoltaic module according to another embodiment of the present invention.

FIG. 14 shows the connected relationship of multiple photovoltaic modules according to an embodiment of the present invention.

### BEST MODE

Hereinafter, exemplary embodiments of the present invention will be described in detail with reference to the accompanying drawings.

However, the present invention is not limited to the given exemplary embodiments described, but may be implemented in a variety of different forms, and one or more of components among the exemplary embodiments may be optionally combined or substituted between embodiments within the scope of the present invention.

Furthermore, terms (including technical and scientific terms) used in the embodiments of the present invention, unless expressly specifically defined and described, are to be interpreted in the sense in which they would be understood by a person of ordinary skill in the art to which the present invention belongs, and commonly used terms, such as dictionary-defined terms, are to be interpreted in light of their contextual meaning in the relevant art.

Furthermore, the terms used in the embodiments of the invention are intended to describe the embodiments and are not intended to limit the invention.

In this specification, the singular may include the plural unless the context otherwise requires, and references to “at least one (or more) of A and (or) B and C” may include one or more of any combination of A, B, and C that may be assembled.

In addition, the terms first, second, A, B, (a), (b), and the like may be used to describe components of embodiments of the invention. Such terms are intended only to distinguish one component from another, and are not intended to limit the nature or sequence or order of such components by such terms.

Furthermore, when a component is described as “connected,” “coupled,” or “attached” to another component, it can include cases where the component is “connected,” “coupled,” or “attached” to the other component directly, as well as cases where the component is “connected,” “coupled,” or “attached” to another component that is between the component and the other component.

Furthermore, when described as being formed or disposed “above” or “below” each component, “above” or “below” includes not only when two components are in direct contact with each other, but also when one or more other components are formed or disposed between the two components. Furthermore, when expressed as “above” or “below”, it may include the meaning of upward as well as downward with respect to a single component.

The variant examples according to this embodiment may include some configuration of each embodiment and some configurations of another embodiment. In other words, the variant example may include one embodiment of various embodiments, but some configurations are omitted and some configurations of another embodiment corresponding to the omitted configurations are included. Or, it may be the other way around. The features, structures, and effects described in the embodiments are included in at least one embodiment and are not necessarily limited to only one embodiment. Furthermore, the features, structures, and effects illustrated in each embodiment can be combined or modified with respect to other embodiments by a person having ordinary knowledge in the field to which the embodiments belong. Therefore, the contents related to such combinations and modifications should be interpreted as being included in the scope of embodiments.

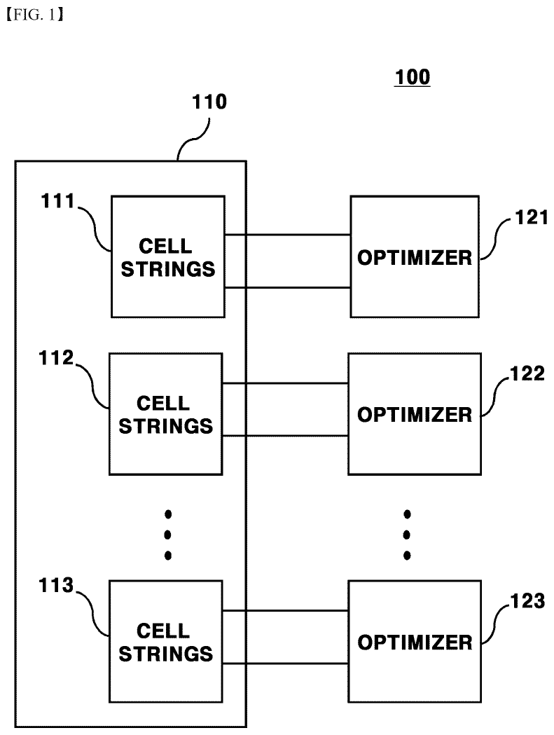

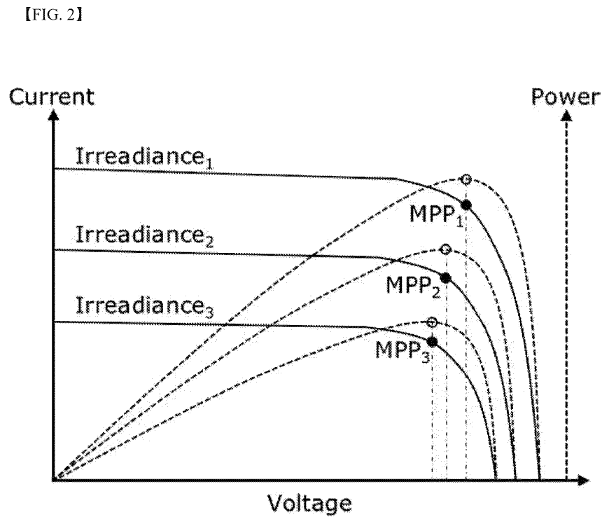

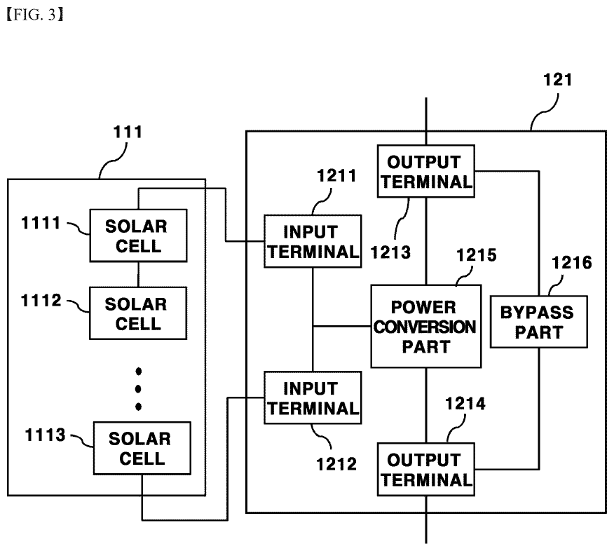

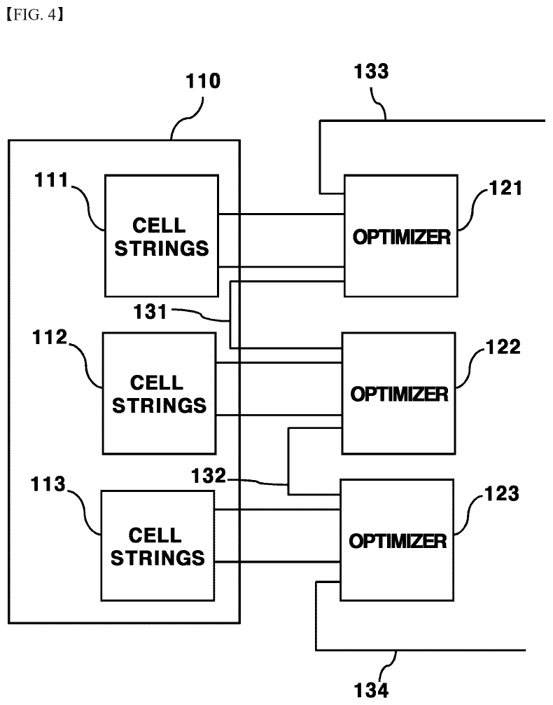

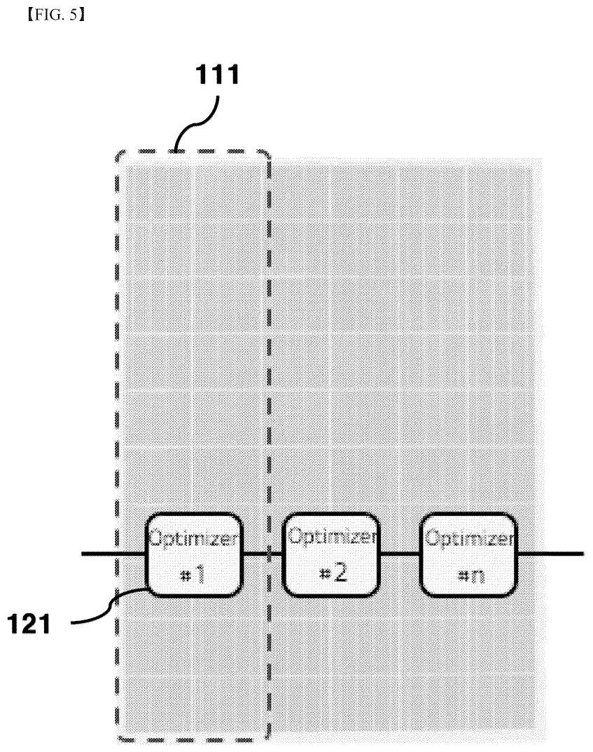

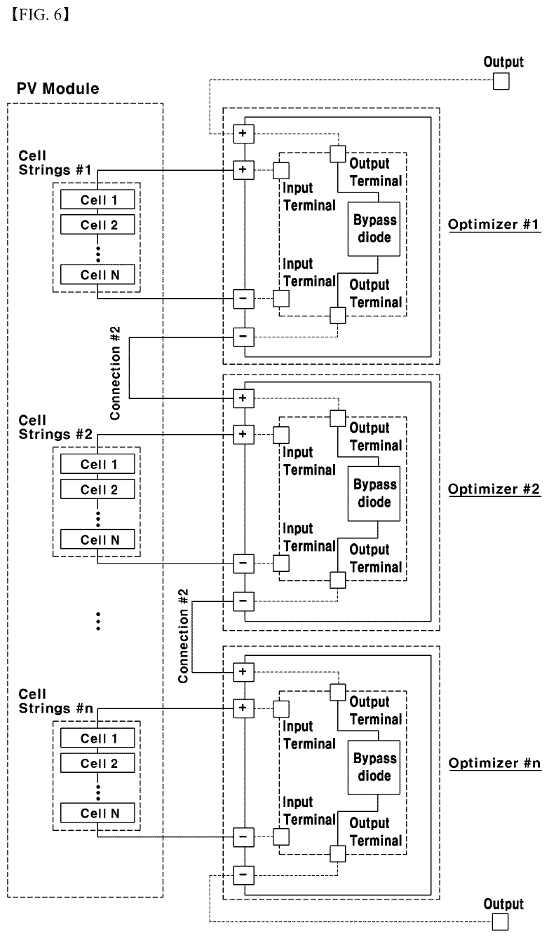

FIG. 1 is a block diagram of a photovoltaic module according to an exemplary embodiment of the present invention, FIG. 2 is a drawing for explaining the maximum power point tracking control, FIG. 3 is a block diagram that specifies the relationship between the cell string and the optimizer according to an embodiment of the present invention, FIG. 4 shows the connected relationship between optimizers according to an embodiment of the present invention, FIG. 5 shows the position of each optimizer according to an embodiment of the present invention, and FIG. 6 shows an embodiment of a photovoltaic module according to an exemplary embodiment of the present invention.

The photovoltaic module (100) according to an exemplary embodiment of the present invention may include a photovoltaic panel (110) and a plurality of optimizers (121, 122, 123).

A photovoltaic module according to an embodiment of the present invention may be a module that converts the power generated by a photovoltaic panel into power suitable for a load or battery. It may be expressed as a solar module, a solar power module, etc.

The photovoltaic panel (110) may include a plurality of cell strings. Solar cells that perform solar power generation may be expressed as a unit of cell strings in which a plurality of cells is connected in series.

A cell string may include at least one cell, and if it includes multiple cells, the multiple cells may be connected in series. A cell string may be a solar cell string that includes a photovoltaic cell. A solar cell string may form a photovoltaic (PV) panel. A photovoltaic panel (110) may also be referred to as a solar panel or a solar PV panel. Solar cells generate electricity using the photovoltaic effect. The photovoltaic effect is the emission of electrons when light of a certain frequency or higher hits a certain metal material. Electricity is generated by forming a pn junction using a P-type semiconductor and an N-type semiconductor, and using the electrons generated by the photovoltaic effect to generate current. Solar cells are formed using silicon and can be formed in the form of wafers. Solar cells are located on the exterior walls, rooftops, etc. of fields or buildings that can receive sunlight well to generate electricity using sunlight. At this time, solar cells can be formed as BIPV (Building Integrated Photovoltaics), which is formed as an integral part of the building.

Since the amount of power generated by a single solar cell is insufficient for use in a load or power system, a string of solar cells can be connected in series, rather than a single solar cell, to form a solar cell string that generates power at a suitable size for use. A solar cell string may be the basic unit for generating electricity. Multiple basic units, cell strings, can be formed into panels to create a solar power panel. Solar cells have different voltage-current characteristics depending on the amount of sunlight and temperature, as shown in FIG. 2, and the maximum power point (MPP) also fluctuates. (Power generated =voltage X current). Multiple optimizers (121, 122, 123) may control the output power of each of the cell strings (111).

The optimizer according to an exemplary embodiment of the present invention controls the photovoltaic cells to operate at the maximum power point (MPP), which is the operating point at which the photovoltaic cells generate the maximum amount of power under each condition. Here, the optimizer may include module-level power electronics (MLPE).

This is called Maximum Power Point Tracking (MPPT), and the efficiency of solar power generation can be increased by using Maximum Power Point Tracking. In solar power generation, the maximum power can be the power at about 80% of the maximum voltage, not the maximum voltage, depending on the characteristics of the relationship between current and voltage and the relationship between voltage and power. Since the maximum power point keeps changing depending on the magnitude of the voltage and current generated by the photovoltaic panel, the point that can generate the maximum power point must be continuously searched. In other words, the magnitude of the voltage and current can be varied to achieve maximum power, not maximum voltage. In other words, it may reduce the voltage and increase the current in the direction of increasing the power, or increase the voltage and reduce the current.

In order to perform maximum power point tracking for multiple cell strings, individual control of each cell string may be required. For example, if a foreign substance interferes with light reception or a certain cell string is shaded, the power generation level may differ from that of other cell strings, so an operation mode that converts the power outputted from the cell string as well as an operation other than power conversion may be required. It may be necessary to output the power directly without converting it from the cell string or to bypass the cell string. For each situation, a device with multiple operating modes is required that can operate in the most suitable mode for the power outputted from each cell string. For example, the optimizer (121) can operate in multiple modes, including power conversion mode (first mode), input/output connection mode (second mode), and bypass mode (third mode), to operate in the most suitable mode for each situation. In addition to the power conversion mode, input/output connection mode, and bypass mode, other operation modes may be included depending on the design.

Each optimizer (121, 122, 123) may be spaced apart from each other and placed in the area corresponding to each cell string (111, 112, 113). Each of the plurality of optimizers (121, 122, 123) is configured as an independent module, but may be placed in an area corresponding to each of the cell strings (111, 112, 113) that perform maximum power point tracking in an area of the photovoltaic panel (110). At this time, it may be located in a position corresponding to the output terminal of each cell string (111, 112, 113). In order to individually control each cell string, if one optimizer is used, a large number of cables are required to connect each cell string and the optimizer, and the work of connecting the cables is required. The optimizer according to an embodiment of the present invention includes a plurality of optimizers (121, 122, 123) that are formed separately to individually control each cell string, but when the optimizer (121) is located in a separate location from the cell string (111), the optimizer (121) can be located on the photovoltaic panel area where each cell string is located, as cables are still required. This allows the optimizer (121), which is individually connected and controlled with the cell string (111), to be directly connected, reducing cable connections and facilitating operation.

The cell strings (111) must receive sunlight, so they are placed on the first surface of the photovoltaic module (100), and each optimizer (121) can have a separately connected cell string (111) placed on the second surface, which is the opposite surface of the first surface. On the second surface of the photovoltaic module (100), the output terminals of both ends of the cell string (111) are derived, and the optimizer (121) is located at the position where the output terminals of both ends of the cell string (111) are derived, so that it can be directly connected to the input terminals of the optimizer. The optimizer (121) may include an input terminal (1211, 1212), an output terminal (1213, 1214), a power conversion unit (1215), and a bypass unit (1216).

The input terminals (1211, 1212) may include two input terminals connected to the output terminals at both ends of each cell string (111). As shown in FIG. 3, each cell string (111) may be connected in series with multiple solar cells (1111 to 1113), and the cell strings (111) connected in series have two output terminals on both ends that are externally connected. At this time, the output terminals on both ends may be connected to the second surface of the photovoltaic module (100). The output terminals at both ends of each of the cell strings may be directly connected to the two input terminals (1211, 1212) of the optimizer and the optimizer itself. The two input terminals (1211, 1212) are connected to the output terminals at both ends of the cell string (111) so that they can receive the power generated by the cell string (111).

The output terminals (1213, 1214) are connected to another optimizer or to the outside. The output terminals (1213, 1214) may also include two output terminals. If the optimizer is connected in series between optimizers, and the optimizer is located between other optimizers, the two output terminals (1213, 1214) are connected to two neighboring optimizers, respectively. The outputs of multiple optimizers (121, 122) are connected in series so that the maximum power can be outputted to the outside. If the optimizer is located at the position corresponding to the output terminal to the outside, one of the two output terminals (1213, 1214) is connected to another optimizer, and the other is connected to the outside. Here, the outside may a configuration located outside the photovoltaic module, which may be a grid, load, or battery. Or, it may be a power conversion device such as an inverter. The outputs of each optimizer are connected in series and outputted to the outside.

The output terminals (1213, 1214) connected to the other optimizers may be connected via the connection unit (131) embedded in the photovoltaic panel (110). As shown in FIG. 4, the optimizer (121) may be connected to the photovoltaic panel (110) via a connection unit (131) built into the photovoltaic panel when connected to another optimizer. The connection unit built into the photovoltaic panel (110) may include a bus bar or a cable. At this time, the output terminal may be directly connected to the bus bar, etc. embedded in the photovoltaic panel (110). At this time, the connection unit (131) embedded in the photovoltaic panel (110) may be drawn to the second surface of the photovoltaic module (100) like the output terminals at both ends of the cell string. The connection unit (131) built into the photovoltaic panel (110) may be directly connected to the two output terminals (1213, 1214) of each optimizer inside the optimizer. At this time, the connection unit (131) embedded in the photovoltaic panel (110) may be insulated and formed so that the cell strings and the inside of the photovoltaic panel (110) are not electrically connected to each other. When using the connection unit (131) embedded in the photovoltaic panel (110), the connection location may be limited, but it can be connected directly without a separate cable.

Alternatively, the output terminals (1213, 1214) connected to the other optimizers or the outside can be connected via an external connection unit (132) rather than the connection unit embedded in the photovoltaic panel (110). When using the connection unit (132) outside the photovoltaic panel (110), a conductor such as a cable is used, so the connection position or connection form may be freely implemented. However, the cables may be exposed to the outside, increasing the risk of electric shock. Depending on the installation or working environment, the connection unit (131) built into the photovoltaic panel (110) or the connection unit (132) outside the photovoltaic panel (110) can be used.

The power conversion unit (1215) can convert the output power of each cell string (111) inputted through the input terminals (1211, 1212) and output it to the output terminals (1213, 1214). The power conversion unit (1215) can convert the voltage of the power of the cell string (111) and output it to the output terminal (1213, 1214). At this time, the power conversion unit (1215) can perform maximum power point tracking for each cell string (111). If some of the cell strings in a plurality of cell strings generate lower voltage than other cell strings due to shading, etc., it is necessary to output the voltage of the other cell strings as is without power conversion to reduce the voltage difference between each cell string to reduce loss and increase efficiency. At this time, the power conversion unit (1215) of each optimizer can adjust the power conversion so that the voltage between the cell strings is equal.

The power conversion unit (1215) may include at least one of a buck converter, a boost converter, and a buck-boost converter. The power conversion unit (120) may include a DC-DC converter, which may include at least one of a buck converter, a boost converter, and a buck-boost converter. The power conversion unit (120) may be implemented as a buck converter that lowers the voltage by comprising an upper switch, a lower switch, and an inductor. It may also be implemented as a boost converter that increases voltage by consisting of an inductor, an upper switch, and a lower switch, and as a buck-boost converter that lowers or increases voltage by consisting of a first upper switch, a first lower switch, an inductor, a second upper switch, and a second lower switch. Capacitors may be connected in parallel to the input and output terminals of each converter.

The bypass unit (1216) is connected in parallel between the two output terminals (1213, 1214) mentioned above.

The bypass unit (1216) can create a bypass path at the output terminals (1213, 1214) that bypasses the connection of the input terminals (1211, 1212) connected to the power conversion unit (120) or the cell string (111). A bypass path can be created to pass the other optimizer externally or to another optimizer without performing power conversion. For example, when a failure occurs in a photovoltaic module containing a cell string, or when there is no power inputted to the power conversion device because the input terminals (1211, 1212) are not connected, the bypass unit (1216) may provide a bypass path. In addition, when a hot-spot occurs in the photovoltaic panel, the bypass unit (1216) can also suppress heat generation by providing a bypass path for the output current to lower the current value flowing through the photovoltaic panel. This prevents the increase in the amount of heat generated by the increase in the impedance of the photovoltaic panel when a current greater than the output current of the photovoltaic panel is forced to flow.

The power conversion unit (1215) or the bypass unit (1216) can be operated by the control unit, and the control unit can transmit control signals to each configuration to operate in the most suitable mode according to information such as input/output voltage, current, and temperature. It can also operate in the corresponding mode according to the control signal from the external control unit or the user's input.

As explained earlier, the optimizer that individually controls each cell string (111) is located at the position of the corresponding cell string (111), as shown in FIG. 5. A photovoltaic module according to an embodiment of the present invention may be a smart photovoltaic module (PV module) including a cell string optimizer, and may comprise at least one cell string (111) consisting of at least one cell and a cell string optimizer electrically connected to the individual cell strings. The output of the optimizer may be connected in series with another optimizer. As shown in FIG. 6, it can include multiple cell strings and each optimizer, and multiple optimizers may be connected in series (Connection #1) through the conductors embedded in the photovoltaic panel. Alternatively, it can be connected via an external conductor when connected in series (Connection #2). The power generated by the optimizer can be outputted to the output terminal. The optimizer can vary at least one parameter associated with the cell string to optimize the amount of power generated by the corresponding cell string. The optimizer may include at least one power conversion unit for optimizing the amount of power generated, and the power conversion unit may be configured as a buck, boost, or buck-boost converter. The optimizer may include diodes connected in parallel to the output terminals to optimize the amount of power generated by the photovoltaic module. To prevent electric shock, the optimizer may act to isolate individual cell string voltages. In addition, the photovoltaic module may include a conductor (cable) for connecting to another photovoltaic module. In addition, the optimizer may be electrically connected to an array consisting of a plurality of cell strings connected in series, in parallel, or in series-parallel. In other words, it may also receive input from multiple cell strings rather than from a single cell string.

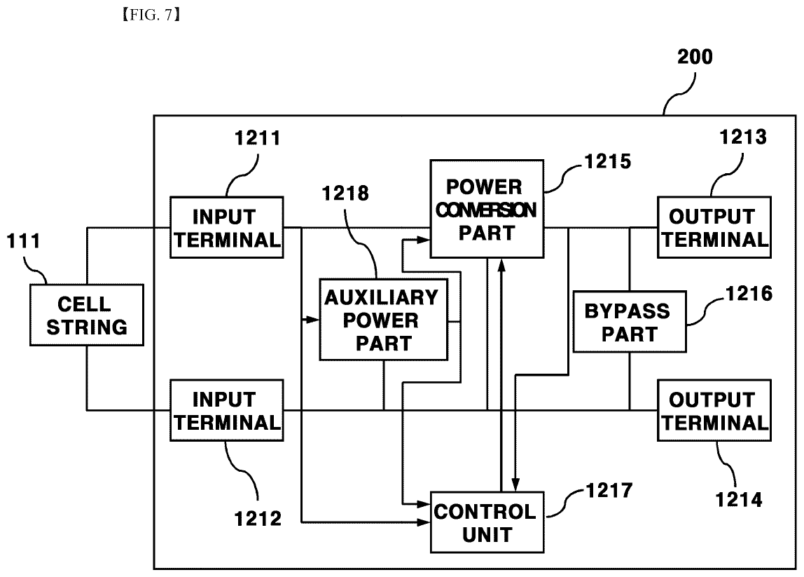

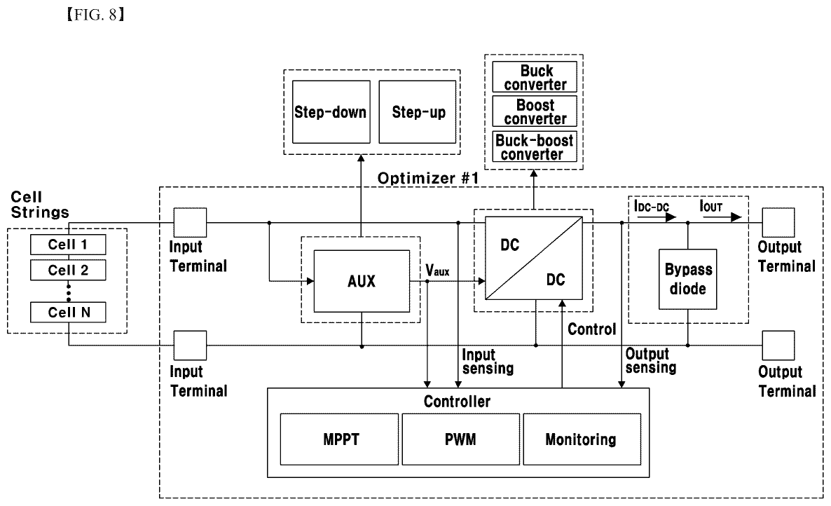

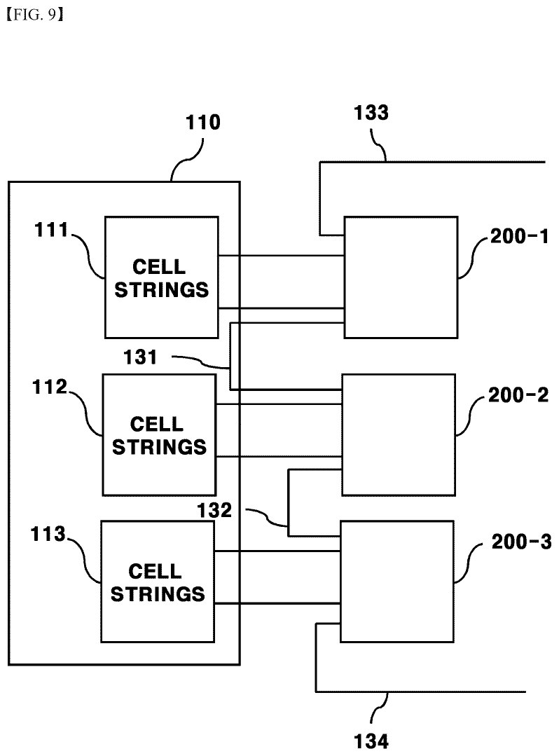

FIG. 7 is a block diagram of an optimizer module according to an embodiment of the present invention, FIG. 8 shows an embodiment of an optimizer module according to an embodiment of the present invention, and FIG. 9 is a block diagram of a photovoltaic module according to another embodiment of the present invention. A detailed description of each configuration of FIGS. 7 to 9 corresponds to a detailed description of the photovoltaic modules of FIGS. 1 to 6, and the following redundant descriptions will be explained briefly. An optimizer module (200) according to an embodiment of the present invention may include an input terminal (1211, 1212), a power conversion unit (1215), an output terminal (1213, 1214), and a control unit (1217), and may include an auxiliary power supply (1218) and a bypass unit (1216).

The input terminals (1211, 1212) are connected to the cell string (111). Two input terminals may be included to connect to both ends of the cell string (111). The output power of the cell string (111) may be inputted into the input terminals (1211, 1212). One of the input terminals (1211, 1212) may be connected to the (+) terminal of the cell string (111) and the other to the (-) terminal of the cell string (111).

The power conversion unit (1215) converts the power inputted to the input terminal (1211). The power conversion unit (1215) can convert the output power of each cell string (111) inputted through the input terminals (1211, 1212) and output it to the output terminals (1213, 1214). The power conversion unit (1215) can convert the voltage of the power of the cell string (111) and output it to the output terminal (1213, 1214). At this time, the power conversion unit (1215) can perform maximum power point tracking for each cell string (111). If some of the cell strings in a plurality of cell strings generate lower voltage than other cell strings due to shading, etc., it is necessary to output the voltage of the other cell strings as is without power conversion to reduce the voltage difference between each cell string to reduce loss and increase efficiency. At this time, the power conversion unit (1215) of each optimizer can adjust the power conversion so that the voltage between the cell strings is equal.

The power conversion unit (1215) may include at least one of a buck converter, a boost converter, and a buck-boost converter. The power conversion unit (120) may include a DC-DC converter, which may include at least one of a buck converter, a boost converter, and a buck-boost converter. The power conversion unit (120) may be implemented as a buck converter that lowers the voltage by comprising an upper switch, a lower switch, and an inductor. It can also be implemented as a boost converter that increases voltage by consisting of an inductor, an upper switch, and a lower switch, and as a buck-boost converter that lowers or increases voltage by consisting of a first upper switch, a first lower switch, an inductor, a second upper switch, and a second lower switch. Capacitors may be connected in parallel to the input and output terminals of each converter.

The output terminals (1213, 1214) are connected to another optimizer module or to the outside.

The output terminals (1213, 1214) may also include two output terminals. If the optimizer modules can be connected in series between optimizer modules, and the optimizer module is located between other optimizer modules, the two output terminals (1213, 1214) may be connected to each of the two neighboring optimizer modules, and the output of multiple optimizer modules may be connected in series to output the maximum power to the outside. If the optimizer module is located at the position corresponding to the output terminal to the outside, one of the two output terminals (1213, 1214) may be connected to one other optimizer module that is adjacent to it, and the other may be connected to the outside. Here, the outside is a configuration located outside the optimizer module, which may be a grid, load, or battery. Or, it can be a power conversion device such as an inverter.

The control unit (1217) controls the power conversion unit (1215) according to the power inputted to the input terminal (1211). The control unit (1217) controls the power conversion unit (1215) to convert the power inputted to the input terminal (1211). The output power of the cell string (111) inputted to the input terminal (1211) is maximized, and the control unit (1217) can control the power conversion unit (1215). The control unit can transmit control signals to each configuration to operate in the most suitable mode according to information such as input/output voltage, current, and temperature. It can also operate in the corresponding mode according to the control signal from an external control unit or the input from the user.

The control unit (1217) can detect and monitor data from the input terminal side, the output terminal side, and the inside of the optimizer module, and control the power conversion unit (1215) accordingly. For example, it can detect the power of the cell string (111) inputted to the input terminal (1211), the output power or output current of the power conversion unit (1215), or the current flowing through the output terminal (1213). In addition, the control unit (1217) can control the auxiliary power unit (1218), bypass unit (1216), etc.

The bypass unit (1216) may be connected in parallel between two output terminals (1213, 1214).

The bypass unit (1216) can create a bypass path between the output terminals (1213, 1214) that bypasses the connection with the power conversion unit (1215). A bypass path can be created to directly connect another optimizer module to the outside or to another optimizer module without performing power conversion. For example, when a failure occurs in a photovoltaic module containing a cell string, or when there is no or low power inputted to the power conversion unit (1215) due to an open input terminal (1211, 1212), the bypass unit (1216) can provide a bypass path. In addition, when a hot-spot occurs in the photovoltaic panel, the bypass unit (1216) can also suppress heat generation by providing a bypass path for the output current to lower the current value flowing through the photovoltaic panel. This prevents the increase in the amount of heat generated by the increase in the impedance of the photovoltaic panel when a current greater than the output current of the photovoltaic panel is forced through.

The bypass unit (1216) may be conducted if the first current outputted from the power conversion unit (1215) is lower than the second current flowing to the output terminal. If the first current converted and outputted from inside the optimizer module (200) is lower than the second current flowing through the output terminal (1213) connected to another optimizer module, the current can flow from another output terminal (1213) to inside the optimizer module (200). This may cause a failure or other error in the optimizer module (200) or a power waste problem. Therefore, in this case, the current flowing through the output terminal (1213) can flow through the bypass unit (1216) to bypass the optimizer module (200). Here, the bypass unit (1216) may include a diode. A diode allows current to flow in only one direction, so it can only bypass current in that direction.

The auxiliary power unit (1218) can generate auxiliary power using the power inputted to the input terminal (1211). The optimizer module (200) requires a power supply to convert power or perform control. The auxiliary power unit (1218) generates auxiliary power using the power inputted to the input terminal (1211) and can provide the generated auxiliary power to the power conversion unit (1215) or the control unit (1217).

The auxiliary power unit (1218) can operate in either step-down or step-up mode. The power inputted to the input terminal (1211) may vary depending on the amount of photovoltaic power generation, but the auxiliary power supply required for the operation of the power conversion unit (1215) or the control unit (1217) may not vary. Therefore, if the voltage of the input power is lower than the voltage of the auxiliary power, the auxiliary power unit (1218) operates in step-up mode, and if the voltage of the input power is higher than the voltage of the auxiliary power, the auxiliary power unit (1218) can operate in step-down mode.

The optimizer module (200) can be implemented with a circuit diagram such as that shown in FIG. 8. The optimizer module (200) is a module that optimizes the output power of the cell string and may include a power conversion unit (1215) such as a DC-DC converter and a control unit (1217) such as a controller. The DC-DC converter receives power generated from the cell string through the input terminal, converts the power, and outputs it through the output terminal. The controller can detect at least one parameter or control the DC-DC converter according to the detected parameter. The controller controls the DC-DC converter to maximize the power generated from the photovoltaic panel. It may also include a bypass unit (1216), which is a bypass diode. The bypass diode conducts when the second current, I_out, is higher than the first current, I_DC-DC, allowing I_out to be bypassed. It can also include an auxiliary power unit (1218) called AUX. The auxiliary power unit receives voltage from the cell string and generates the power required for the controller and DC-DC converter. At this time, the auxiliary power unit can operate in at least one step-down or step-up mode.

Here, the DC-DC converter can be composed of at least one buck, boost, or buck-boost converter, and the optimizer module connected to multiple cell strings can be connected in series. Through series connection, a voltage higher than the output voltage of the individual cell-string optimizer module may be formed.

A photovoltaic module according to an embodiment of the present invention may include a photovoltaic panel (110) comprising a plurality of cell strings (111, 112, 113) and a plurality of optimizer modules (200-1, 200-2, 200-3) for controlling the output power of each of the said cell strings. At this time, each of the optimizer modules may be spaced apart and placed in the area corresponding to each cell string.

The output terminals (1213, 1214) connected to the other optimizers may be connected via the connection unit (131) embedded in the photovoltaic panel (110). As shown in FIG. 9, the optimizer module (200-1) may be connected to another optimizer module (200-2) via the connection unit (131) embedded in the photovoltaic panel (110). At this time, the connection unit embedded in the photovoltaic panel (110) may include a bus bar or a cable. At this time, the output terminal may be directly connected to the bus bar, etc. embedded in the photovoltaic panel (110). At this time, the connection unit (131) embedded in the photovoltaic panel (110) may be drawn to the second surface of the photovoltaic module, such as the output terminals at both ends of the cell string. The connection unit (131) built into the photovoltaic panel (110) may be directly connected to the two output terminals (1213, 1214) of each optimizer inside the optimizer. At this time, the connection unit (131) embedded in the photovoltaic panel (110) may be insulated and formed so that the cell strings and the inside of the photovoltaic panel (110) are not electrically connected to each other. When using the connection unit (131) embedded in the photovoltaic panel (110), the connection location may be limited, but it can be connected directly without a separate cable.

Alternatively, the output terminals (1213, 1214) connected to the other optimizers or the outside may be connected via an external connection unit (132) rather than the connection unit embedded in the photovoltaic panel (110). When using the connection unit (132) outside the photovoltaic panel (110), a conductor such as a cable is used, so the connection position or connection form may be freely implemented. However, the cables may be exposed to the outside, increasing the risk of electric shock. Depending on the installation or working environment, the connection unit (131) built into the photovoltaic panel (110) or the connection unit (132) outside the photovoltaic panel (110) may be used.

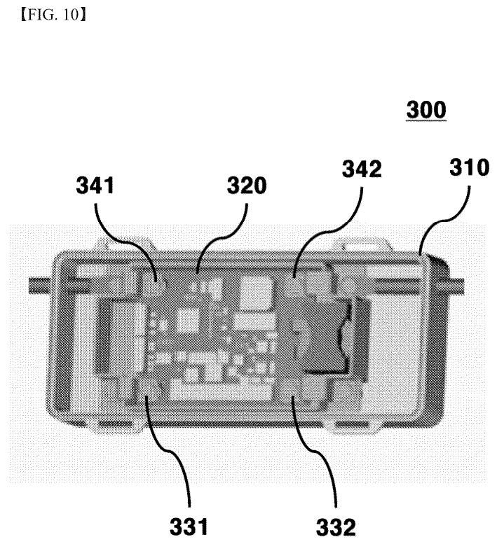

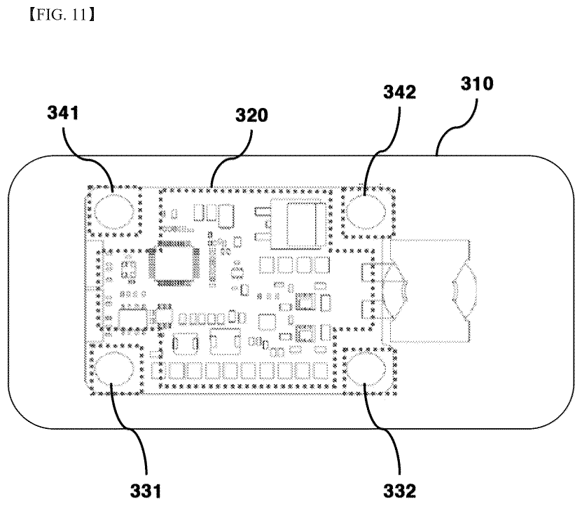

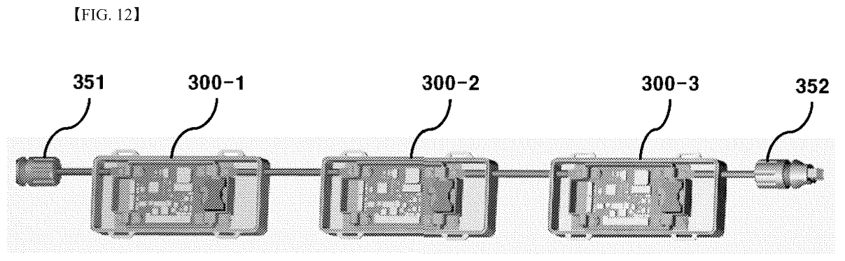

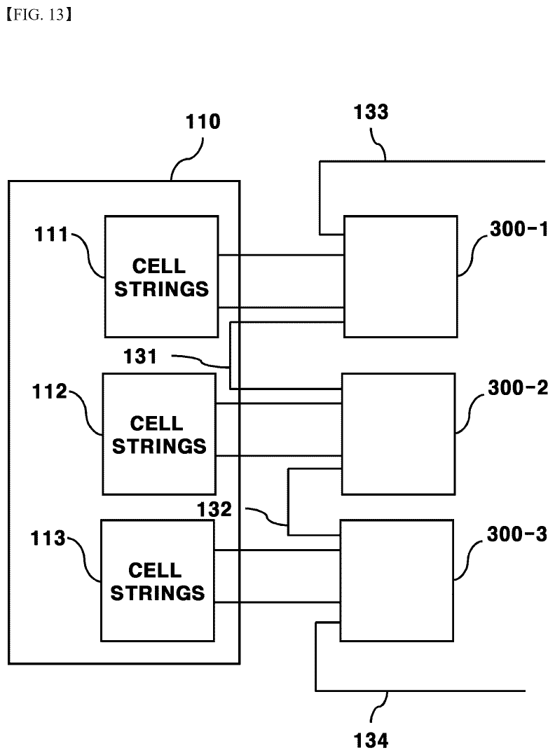

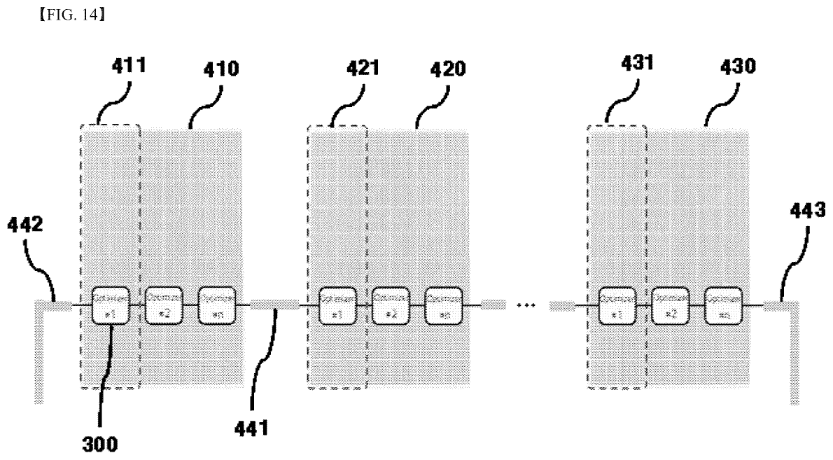

FIG. 10 is a perspective view of an optimizer module according to an embodiment of the present invention, FIG. 11 shows the inside of the case of an optimizer module according to an embodiment of the present invention, FIG. 12 shows the connected relationship of multiple optimizer modules according to an embodiment of the present invention, FIG. 13 is a block diagram of a photovoltaic module according to another embodiment of the present invention, and FIG. 14 shows the connected relationship of multiple photovoltaic modules according to an embodiment of the present invention. A detailed description of each configuration of FIGS. 10 to 14 corresponds to the detailed description of the photovoltaic modules of FIGS. 1 to 9, and the following redundant descriptions will be explained briefly.

The optimizer module (300) according to an embodiment of the present invention may include a case and an optimizer (320) placed inside the case. The optimizer (320) comprises an input terminal (331,332), a power conversion unit (320), and an output terminal (342, 3434), and may include an auxiliary power unit and a bypass unit.

The case (310) may include a case body and a case cover (not shown) covering the case body, and may include an optimizer (320) that is placed inside the case body. The optimizer (300) may include two input terminals (321, 332) and two output terminals (341, 342).

The two input terminals (331, 332) are connected to the output terminals at both ends of the cell string, and the optimizer (320) may include a power conversion unit that converts the output power of the cell string and a control unit that controls the power conversion unit according to the output power of the cell string.

The interior of the case (310) may be filled with a heat-dissipating material. Heat is generated when converting electricity, and the heat can be dissipated to the outside to prevent errors caused by heat. The interior of the case (310) may be filled with silicon or epoxy material.

The interior of the case (310) may be formed with a waterproof structure. The case (310) may be formed on one surface of the photovoltaic module and, since it is located outdoors, may be exposed to rain, so it may be formed with a waterproof structure. As shown in FIG. 10, a waterproof structure may be formed on the optimizer (320) connected to each connection terminal. In other words, a case internal structure having a waterproof structure may be formed inside the case, and an optimizer (320) may be placed inside the waterproof structure to protect the configuration placed on the optimizer (320).

The optimizer (320) may be detachable from the case (310) body. The optimizer (320) may be attached to or detached from the case (310) by connecting or disconnecting it to the input terminal (331, 332) or the output terminal (341, 342). Each terminal may be screwed together. In the event of a failure of the optimizer (320), only the optimizer (320) may be detached and replaced or repaired, rather than the entire optimizer module (300). Alternatively, it may be attached to the case (310) body in various ways, such as hooking or soldering.

The input terminals (331, 332) may be connected to the photovoltaic panel of the photovoltaic module to which the optimizer module (300) is mounted, and may receive the output power of the cell string. The cell strings (111) connected in series may have two output terminals on both ends drawn out to the outside, and the output terminals on both ends may be drawn out to the second surface of the photovoltaic module (100). The output terminals at both ends of each of the above-mentioned cell strings may be directly connected inside the case (320) with the two input terminals (331, 332) of the optimizer module (300) mentioned above. The two input terminals (331, 332) are each connected to the output terminals at both ends of the cell string (111) so that they can receive the power generated by the cell string (111).

The output terminals (341, 342) are connected to another optimizer module or to the outside. The output terminals (341, 342) may also include two output terminals. If the optimizer module is connected in series between optimizer modules and the optimizer module is located between other optimizer modules, the two output terminals (341, 342) may be connected to two neighboring optimizer modules, respectively. The output of multiple optimizer modules is connected in series to output maximum power to the outside. If the optimizer module is located at the position corresponding to the output terminal to the outside, one of the two output terminals (341, 342) may be connected to another optimizer module, and the other may be connected to the outside.

Here, the outside is a configuration located outside the photovoltaic module, which may be a grid, load, or battery. Or, it may be a power conversion device such as an inverter. The outputs of each optimizer are connected in series and output to the outside.

The output terminals (341, 342) connected to the other optimizer modules may be connected via the connection unit (131) embedded in the photovoltaic panel (110). As shown in FIGS. 12 and 13, the optimizer module (300-1) may be connected to another optimizer module (300-2) via the connection unit (131) embedded in the photovoltaic panel (110). The connection unit embedded in the photovoltaic panel (110) may include a bus bar or a cable. At this time, the output terminal may be directly connected to the bus bar, etc. embedded in the photovoltaic panel (110). At this time, the connection unit (131) embedded in the photovoltaic panel (110) may be drawn to the second surface of the photovoltaic module (100) like the output terminals at both ends of the cell string. The connection unit (131) built into the photovoltaic panel (110) may be directly connected to the two output terminals (341, 342) of each optimizer module and inside the optimizer module case (310). At this time, the connection unit (131) embedded in the photovoltaic panel (110) may be insulated and formed so that the cell strings and the inside of the photovoltaic panel (110) are not electrically connected to each other. When using the connection unit (131) embedded in the photovoltaic panel (110), the connection location may be limited, but it may be connected directly without a separate cable.

Alternatively, the output terminals (341, 342) that are connected to the other optimizers or the outside may be connected via an external connection unit (132) rather than the connection unit embedded in the photovoltaic panel (110). When using the connection unit (132) outside the photovoltaic panel (110), a conductor such as a cable is used, so the connection position or connection form can be freely implemented. However, the cables may be exposed to the outside, increasing the risk of electric shock. Depending on the installation or working environment, the connection unit (131) built into the photovoltaic panel (110) or the connection unit (132) outside the photovoltaic panel (110) may be used.

The output terminals (341, 342) may be connected to another optimizer module or to an external device, and the output terminals (341, 342) may be connected in series when connected to another optimizer module. The output terminals (341, 342) may be connected to conductors such as cables or bus bars that are fed into the inside of the case (310) through holes formed on the outside of the case (310) by screwing them together.

The case (310) may include a case body and a case cover, and the case (310) may include a waterproof function. In addition, the interior of the case (310) may be filled with a material that allows heat transfer. For example, the interior of the case (310) may be filled with a material such as silicone or epoxy, which is easy to transfer heat. The optimizer, which optimizes the cell strings, may be easily replaced by being detachable from the case (310). It may be electrically connected to the optimizer module of the cell strings located in other photovoltaic panels through the output terminal. At this time, the output terminal may be connected to a conductor such as a cable to facilitate connection with other photovoltaic panels. The output terminal may be connected through a conductor embedded in the photovoltaic panel, and the conductor embedded in the photovoltaic panel may be replaced with a cable that is not embedded in the photovoltaic panel.

The optimizer (320) may be formed with a circuit configuration that is placed on a substrate inside the case (310). The optimizer (320) consists of input terminals (331, 332), a power conversion unit, and output terminals (342, 3434), and may include an auxiliary power unit and a bypass unit.

The power conversion unit converts the power inputted to the input terminal (331, 332). At this time, the control unit controls the power conversion unit according to the power inputted to the input terminal (331, 332). The control unit can control the power conversion unit so that the output power of the cell string is maximized. The power conversion unit may include at least one of a buck converter, a boost converter, and a buck-boost converter.

The bypass unit may be connected in parallel between the two output terminals (341, 342) and conduct current between the output terminals to form a bypass path. The auxiliary power unit can generate auxiliary power using the output power of the cell string and provide it to the power conversion unit or control unit.

A photovoltaic module according to an embodiment of the present invention may include a photovoltaic panel (110) comprising a plurality of cell strings (111, 112, 113) and a plurality of optimizer modules (300-1, 300-2, 300-3) for controlling the output power of each of the said cell strings. At this time, each of the optimizer modules may be spaced apart from each other and placed in the area corresponding to each cell string.

The output terminals (341, 342) connected to the other optimizers may be connected via the connection unit (131) embedded in the photovoltaic panel (110). As shown in FIG. 12 and. 13, the optimizer module (300-1) may be connected to another optimizer module (300-2) via the connection unit (131) embedded in the photovoltaic panel (110). The connection unit (131) embedded in the photovoltaic panel (110) may be insulated and formed so that the cell strings and the inside of the photovoltaic panel (110) are not electrically connected to each other. When using the connection unit (131) embedded in the photovoltaic panel (110), the connection location may be limited, but it may be connected directly without a separate cable.

Alternatively, the output terminals (341, 342) connected to the other optimizer or the outside may be connected via an external connection unit (132) rather than the connection unit embedded in the photovoltaic panel (110). When using the connection unit (132) outside the photovoltaic panel (110), a conductor such as a cable is used, so the connection location or connection form can be freely implemented. However, the cables may be exposed to the outside, increasing the risk of electric shock. Depending on the installation or working environment, the connection unit (131) built into the photovoltaic panel (110) or the connection unit (132) outside the photovoltaic panel (110) may be used.

Photovoltaic modules (410, 420, 430) may be connected in multiple numbers. As shown in FIG. 14, multiple photovoltaic modules (410, 420, 430) may be connected in series with each other through a conductor (441) or connected to the outside through a conductor (442, 443). Each photovoltaic module (410) may include a photovoltaic panel (411) and the optimizer module (300) described above.

As mentioned above, the optimizer module may be located in a position corresponding to the output terminal of the cell string, thereby reducing the number of cables connecting the photovoltaic panel and the optimizer and facilitating operation.

One having ordinary skill in the art will understand that the exemplary embodiments of the present invention can be implemented in modified forms that do not deviate from the essential features of the above-described embodiments. Therefore, the disclosed methods should be considered in a descriptive rather than a limiting sense. The scope of the present invention is not described in the foregoing description but in the patent claims, and all differences within the equivalent scope thereof should be construed as being included in the present invention.

1. A photovoltaic module, comprising:
a photovoltaic panel comprising a plurality of cell strings; and
a plurality of optimizers each configured to control output power of each of the cell strings,
wherein each of optimizers located at a position corresponding to an output terminal of each of the cell strings.

2. The photovoltaic module of claim 1, wherein each of the optimizers comprises:
two input terminals connected to output terminals at both ends of each of the cell strings;
two output terminals connected to other optimizer or outside, and
a power conversion unit configured to convert output power of each of the cell strings inputted through the input terminals and output it to the output terminals.

3. The photovoltaic module of claim 2, wherein the output terminal connected to the other optimizer is connected via a connection unit embedded in the photovoltaic panel.

4. The photovoltaic module of claim 3, wherein the connection unit embedded in the photovoltaic panel comprises a bus bar or a cable.

5. The photovoltaic module of claim 2, wherein the output terminals at both ends of each of the cell strings are directly connected to the two input terminals of each of the optimizers inside the optimizer.

6. The photovoltaic module of claim 2, wherein the output terminal connected to the other optimizer or the outside is connected via a connection unit at outside of the photovoltaic panel.

7. The photovoltaic module of claim 2, wherein the power conversion unit comprises at least one of a buck converter, a boost converter, and a buck-boost converter.

8. The photovoltaic module of claim 2, wherein each of optimizers comprises a bypass unit connected in parallel between the two output terminals.

9. The photovoltaic module of claim 1, wherein each of optimizers controls output power of each of cell strings with maximum power point tracking (MPPT).

10. The photovoltaic module of claim 1, wherein the plurality of optimizers are mounted on an opposite surface of a surface on which the photovoltaic module is disposed.

11. A photovoltaic system, comprising:
a photovoltaic module; and
a power converting module configured to convert output of the photovoltaic module,
wherein the photovoltaic module comprises:
a photovoltaic panel comprising a plurality of cell strings; and
a plurality of optimizers each configured to control output power of each of the cell strings, and
wherein each of optimizers located at a position corresponding to an output terminal of each of the cell strings.

12. The photovoltaic system of claim 11, wherein each of the optimizers comprises:
two input terminals connected to output terminals at both ends of each of the cell strings;
two output terminals connected to other optimizer or the power converting module; and
a power conversion unit configured to convert output power of each of the cell strings inputted through the input terminals and output it to the output terminals.

13. The photovoltaic system of claim 12, wherein the output terminal connected to the other optimizer is connected via a connection unit embedded in the photovoltaic panel.

14. The photovoltaic system of claim 13, wherein the connection unit embedded in the photovoltaic panel comprises a bus bar or a cable.

15. The photovoltaic system of claim 12, wherein the output terminals at both ends of each of the cell strings are directly connected to the two input terminals of each of the optimizers inside the optimizer.

16. The photovoltaic system of claim 12, wherein the output terminal connected to the other optimizer or the power converting module is connected via a connection unit at outside of the photovoltaic panel.

17. The photovoltaic system of claim 12, wherein the power conversion unit comprises at least one of a buck converter, a boost converter, and a buck-boost converter.

18. The photovoltaic system of claim 12, wherein each of optimizers comprises a bypass unit connected in parallel between the two output terminals.

19. The photovoltaic system of claim 11, wherein each of optimizers controls output power of each of cell strings with maximum power point tracking (MPPT).

20. The photovoltaic system of claim 11, wherein the plurality of optimizers are mounted on an opposite surface of a surface on which the photovoltaic module is disposed.
